(19) United States
(12) Patent Application Publication
(10) Pub. No.: US 2025/0337435 A1
(43) Pub. Date: Oct. 30, 2025

(54) LOSSLESS COMPRESSION METHOD FOR MANAGING TELEMETRY DATA

(71) Applicant: Dell Products L.P., Round Rock, TX (US)

(72) Inventors: Dong-Yu LIU, New Taipei City (TW); Ibrahim SAYYED, Georgetown, TX (US); Danilo O. TAN, Austin, TX (US)

(73) Assignee: Dell Products L.P., Round Rock, TX (US)

(21) Appl. No.: 18/649,571

(22) Filed: Apr. 29, 2024

(51) Int. Cl. H03M 7/30; G06F 16/901

(52) U.S. Cl. CPC H03M 7/6011; G06F 16/9014; H03M 7/3062

(57) ABSTRACT

Disclosed telemetry data management methods obtain, from a component of an information handling system, a component identifier (CID), uniquely indicative of the component, and telemetry samples including a first sample and one or more subsequent samples. The telemetry samples are encoded to create telemetry records, which are stored in a telemetry database. The first sample is stored as an independent record while subsequent samples are stored as dependent records. Independent records contain information sufficient to reconstruct the sample without accessing any other records whereas dependent records are not generally able to recreate the corresponding sample without referencing another record. The dependent records may be differential dependent records that indicate differences between two telemetry samples and omits any telemetry data field for which the two telemetry samples have the same value. Differential data records may include structured data information associating each telemetry data value with the correct telemetry data field.

### TECHNICAL FIELD

The present disclosure pertains to information handling systems and, more particularly, telemetry data generated by information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

For purposes of this disclosure, telemetry and telemetry data encompass substantially any performance, status, configuration data generated and/or reported by a system component including, but not strictly limited to hardware components. Telemetry data can provide extremely valuable insight regarding user behavior, system performance and dependencies, vulnerabilities, and so forth. However, because the amount of telemetry data can be massive, the manner in which telemetry data is stored and organized is critical.

Conventional efforts to conserve telemetry data include approaches represented in FIG. 1. As depicted in FIG. 1, a compression module 90 is applied to each telemetry data sample “S” (91) to produce a corresponding compressed data sample “Z” (92) that is then stored to a database 95 as a record “R” (96). This process is essentially reversed when it is necessary to recreate a sample S from a record R. Such efforts are inherently limited to considering and addressing intra-sample redundancies.

### SUMMARY

In at least one embodiment, disclosed methods and systems for managing telemetry data obtain, from a component of an information handling system, a component identifier (CID) and two or more telemetry samples. The CID is uniquely indicative of the component and the telemetry samples include a first telemetry sample and one or more subsequent telemetry samples. The telemetry samples are processed in accordance with a disclosed lossless compression protocol to create telemetry records, referred to herein simply as records, that are stored in a telemetry database. The stored records may include a record corresponding to each telemetry sample.

In accordance with a disclosed lossless compression technique, the first sample may be stored as an independent record while the subsequent samples may be stored as dependent records. Independent records contain information sufficient to reconstruct the applicable telemetry sample without accessing any other records whereas dependent records are not generally able to recreate the corresponding telemetry sample without referencing at least one other record. In an exemplary embodiment, the dependent records are differential dependent records that indicate one or more differences between two telemetry samples. In at least one such embodiment, a differential dependent record omits any telemetry data field for which the two telemetry samples have the same value. Differential data records may also include structured data information that enables a decoding algorithm to associate each telemetry data value with the correct telemetry data field within the sample.

Differential data records may be chained together. For example, the database records for three telemetry samples sharing a common CID may include an independent record corresponding to the first sample, and two differential dependent records include a differential dependent record indicative of differences between the second and first telemetry samples and a different dependent record indicative of differences between the second and third telemetry samples. In this manner, if there are N telemetry samples for a given CID, N−1 of the corresponding database records may be dependent differential records such that, for any considerable value of N, substantially all of the applicable database records are dependent differential records. For cases in which the number of telemetry data fields monitored and recorded is considerably larger than the number of telemetry data fields that typically change from one sample to the next, those of ordinary skill in the field will readily appreciate the considerable and potentially immense reduction in telemetry storage attainable.

In at least some embodiments, each telemetry sample includes a plurality of key value pairs sharing a common structure and each record includes a CID, a timestamp, and a data value component (DVC) reflecting some or all of the data values in the applicable sample. In at least one embodiment, independent records include each data value of the corresponding telemetry sample and the database record may be generated by encoding the telemetry sample based on a predetermined encoding scheme. An exemplary encoding scheme disclosed herein may be referred to as a key-length-type-value (KLTV) encoding scheme, wherein each value pair in the telemetry sample is represented in the data record by: a key field comprising a number assigned to the telemetry data field; a value field containing the sample's value for the applicable data field; a type field comprising a number indicative of a data type of the value field; and a length field indicative of a length of the value field. In contrast, a dependent record DVC may conserve required storage resources by limiting the sample data values included in the record to telemetry data fields that changed in value relative to the prior telemetry sample. These dependent data records may be implemented as tree structures and may further include structured data information for associating the included data values with the appropriate telemetry data fields.

Embodiments for storing subsequent telemetry samples, i.e., telemetry samples as a differential dependent record performing structured comparison operations including creating an array to hold structured data indicative of the value differences, wherein each element of the array corresponds to an array index value (AIV) and includes a linked list of telemetry data fields corresponding to the AIV. For each value of the AIV from 1 to N, any links in the array element are expanded to identify all telemetry data endpoints for the corresponding telemetry data field. Thus, for example, element 2 of the array, after expanding any linked lists, identifies all endpoints for the telemetry data field #2. For each endpoint value, if the value in the subsequent sample differs from the corresponding endpoint value in the previous sample, the subsequent sample value is included as a key value pair in the patch record along with structured data information sufficient to navigate the structure of the telemetry sample to identify the appropriate placement of the value. No information is recorded in the patch record for endpoint values that were unchanged in the subsequent telemetry sample.

The method may further include decoding operations to recreate a telemetry data sample corresponding to a particular CID and timestamp from one or more records in the telemetry database sharing the CID. Such operations may include, indexing the database with the CID and timestamp to identify a matching record and determining whether the matching record is an independent record or a differential dependent record. For an independent record, the sample may be recreated by simply extracting the data values from the record. For a dependent differential record, recreating the telemetry sample may include indexing the database with the CID to identify a base record, comprising an independent record matching the CID and one or more intermediate records comprising one or more dependent differential records matching the CID and having an earlier timestamp than the timestamp of the record of interest. If there are multiple intermediate records, the corresponding tree structures can be merged to obtain a cumulative patch record indicative of all differences between the record of interest and its corresponding independent record. The telemetry sample of interest may then be created by patching the independent record with the cumulative patch record.

In some embodiments, the CID may be determined based on a concatenation of values for two or more identifying parameters including, as non-limiting examples: an electronic piece part identifier (ePPID), a service tag, a serial number, a model name, and/or any other suitable identifier. The CID may be a hashed CID generated by hashing the concatenated identifier with a predetermined hashing algorithm such as an SHA2 algorithm.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates prior art telemetry data management;

FIG. 2 illustrates an exemplary telemetry data management platform;

FIG. 3 illustrates an exemplary telemetry management process flow;

FIG. 4 illustrates an exemplary telemetry management platform;

FIG. 5 and FIG. 6 illustrate a comparison of two telemetry samples;

FIG. 7 illustrates a method of telemetry data management; and

FIG. 8 illustrates an exemplary information handling suitable for use in conjunction with system and method disclosed in FIGS. 2 through 7.

### DETAILED DESCRIPTION

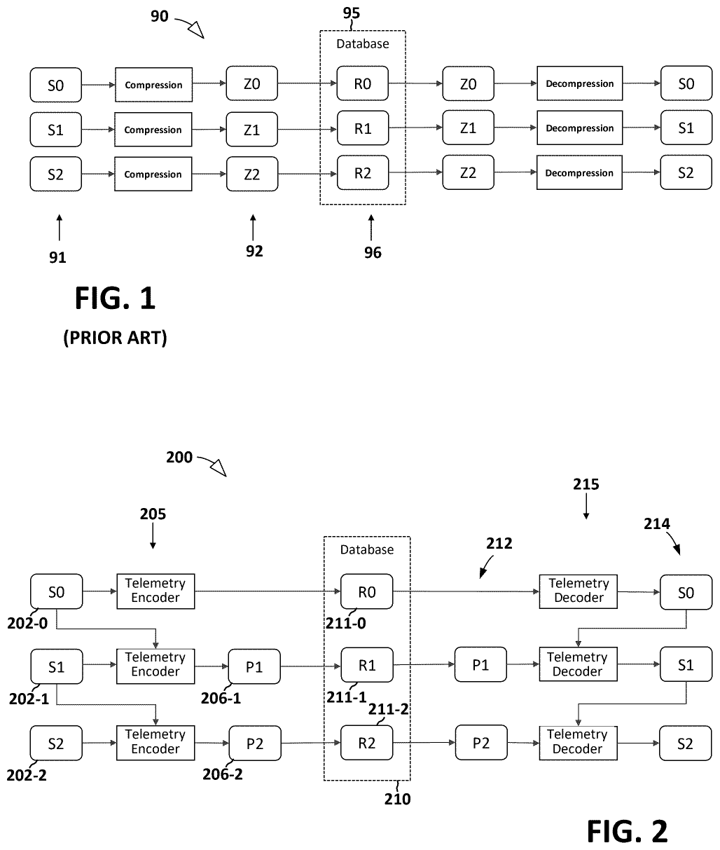

Exemplary embodiments and their advantages are best understood by reference to FIGS. 1-8, wherein like numbers are used to indicate like and corresponding parts unless expressly indicated otherwise.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

Additionally, an information handling system may include firmware for controlling and/or communicating with, for example, hard drives, network circuitry, memory devices, I/O devices, and other peripheral devices. For example, the hypervisor and/or other components may comprise firmware. As used in this disclosure, firmware includes software embedded in an information handling system component used to perform predefined tasks. Firmware is commonly stored in non-volatile memory, or memory that does not lose stored data upon the loss of power. In certain embodiments, firmware associated with an information handling system component is stored in non-volatile memory that is accessible to one or more information handling system components. In the same or alternative embodiments, firmware associated with an information handling system component is stored in non-volatile memory that is dedicated to and comprises part of that component.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

In the following description, details are set forth by way of example to facilitate discussion of the disclosed subject matter. It should be apparent to a person of ordinary skill in the field, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically. Thus, for example, “device 12-1” refers to an instance of a device class, which may be referred to collectively as “devices 12” and any one of which may be referred to generically as “a device 12”.

As used herein, when two or more elements are referred to as “coupled” to one another, such term indicates that such two or more elements are in electronic communication, mechanical communication, including thermal and fluidic communication, thermal, communication or mechanical communication, as applicable, whether connected indirectly or directly, with or without intervening elements.

Referring now to the drawings, FIG. 2 illustrates an exemplary telemetry data management platform 200 featuring an efficient and lossless compression protocol to dramatically reduce storage requirements for telemetry data. Efficient and lossless data compression is achieved at least in part by the use of two different types of data records including a differential dependent type records used for the majority of telemetry data samples. Differential dependent data records represent a data sample by indicating how the sample differs from a previous sample. For cases in which a new data record is frequently quite similar to the preceding data record, differential data records may achieve highly efficient data compression.

FIG. 2 illustrates three telemetry samples 202-0, 202-1, and 202-2 that share a common structure and were generated by the same component of an information handling system. Chronologically, telemetry sample 202-0 was generated before telemetry sample 202-1, which was generated before telemetry sample 202-2.

Disclosed telemetry management features may process the first telemetry sample 202-0 differently than all subsequent telemetry samples 202-1, 202-2, etc. First telemetry sample 202-0 may be encoded by telemetry encoder 205 and stored in telemetry database 210 as database record 211-0. In at least one embodiment, database records 211 corresponding to the first telemetry sample for a given CID, are stored as independent database records while all subsequent telemetry samples with the same CID are processed and stored as differential dependent database records.

Thus, FIG. 2 illustrates that database record R0 211-0 is calculated, derived, or otherwise determined by telemetry encoder 205 based on the telemetry data values of a single telemetry sample, namely, telemetry sample S0 202-0. In contrast, both of the database records R1 211-1 and R2 211-2 generated subsequent to first database record R0 211-0 are determined based on the values of two chronologically adjacent telemetry samples. First database record R1 211-1, for example, is illustrated as being calculated, derived, or otherwise determined based not solely on the corresponding telemetry sample, i.e., telemetry sample 202-1, but also on the chronologically preceding telemetry sample, S0 202-0. Similarly, second database record R2 211-2 is illustrated as being calculated, derived, or otherwise determined based not solely on telemetry sample 202-2, but also on the chronologically preceding telemetry sample, S1 202-1.

In addition, FIG. 2 depicts telemetry encoder 205 generating a patch 206 for each of the subsequent telemetry samples, i.e., telemetry samples S1 202-1 and S2 202-2. Qualitatively, each patch 206 is indicative of differences between two chronologically adjacent telemetry samples. Thus, for example, it may be said that P1 (206-1) reflects S1-S0 where S1-S0 refers to the telemetry data values in S1 that are different from the corresponding telemetry data values in S0. The encoder, patches and database records of FIG. 2 are discussed more specifically below.

FIG. 2 further depicts the retrieval 212 of data records R 211 and the subsequent re-creation or restoration 214 of the corresponding telemetry sample. Again, FIG. 2 depicts a distinction between the first telemetry sample S0 and the subsequent telemetry samples S1 and S2.

As depicted in FIG. 2, decoders 215 restore the first telemetry sample S0 based exclusively on the record R0 211-0 while decoders 215 require a patch input to resolve telemetry samples for the second and third database records R1 and R2.

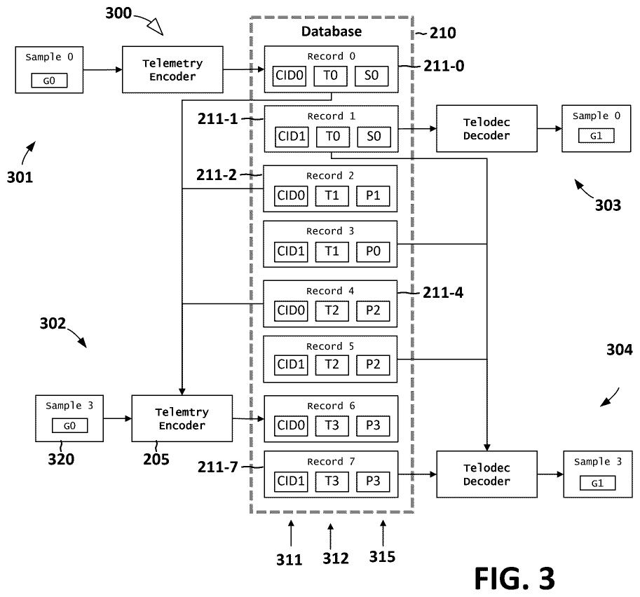

FIG. 3 illustrates an exemplary process flow 300 for disclosed telemetry management features. Specifically, FIG. 3 illustrates four database transactions including a first transaction 301 for storing a telemetry sample as an independent record, a second transaction 302 for storing a telemetry sample as a differential dependent record, a third transaction 303 for retrieving an independent record 303, and a fourth transaction 304 for retrieving a dependent record.

As depicted in FIG. 3, each record 211 in database 210 includes a CID 311, a timestamp 312, and a DVC 315. In at least one embodiment, CID 311 and timestamp 312 are elements of a compound or joint primary key for database 210. FIG. 3 further depicts the DVC 315 as having a sample-like structure for independent records (211-0, 211-1) and a patch-like structure for dependent records (211-2 through 211-7).

As illustrated in FIG. 3, transaction 301 and described previously the first telemetry samples for any given CID are encoded and stored as independent records while any subsequent telemetry sample is stored (transaction 302) as a patch record indicative of differences between the sample under consideration and the preceding sample for the same CID. Thus, as depicted in FIG. 3, telemetry sample 320 corresponding to the fourth telemetry sample from CID0 is processed by encoder 205 against the previous telemetry sample, i.e., the telemetry sample corresponding to record 211-4. However, because record 221-4 is, itself, a patch record, the corresponding telemetry sample must be constructed before comparison with telemetry sample 320. Accordingly, transaction 302 includes references to each of the preceding records associated with CID0. Similarly, transaction 304, involving the restoration of a telemetry sample for CID 1, requires retrieval and processing of the base claim for CID1, i.e., record 211-1, and each intervening record for CID1 that is older than record 211-7, i.e., all CID1 records with timestamps less than T3.

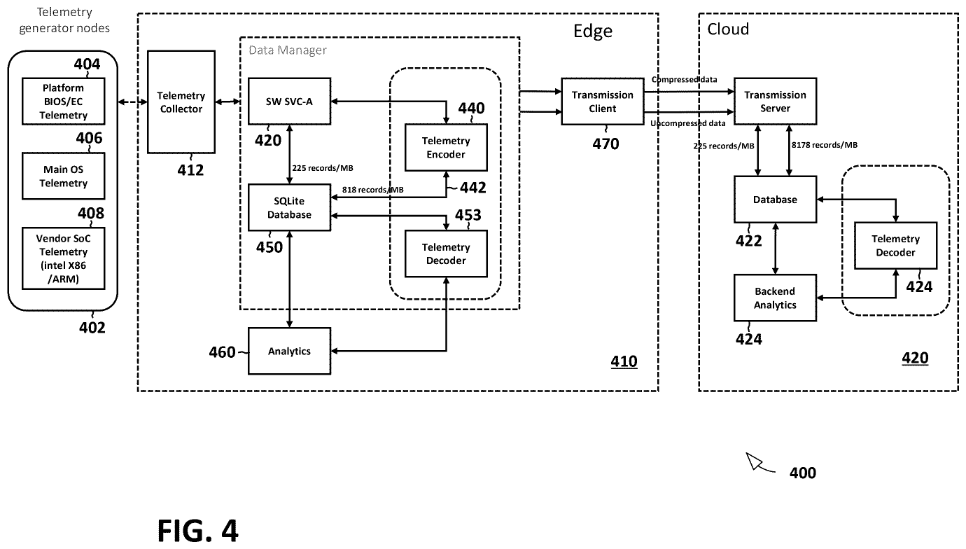

FIG. 4 illustrates an exemplary telemetry management platform 400 implemented in an edge computing environment and employing disclosed telemetry data management features both at the edge 410 and in the cloud 420. As depicted in FIG. 4, telemetry generator nodes 402 including, as representative examples, platform bios/embedded controller telemetry 404, main operating system telemetry 406, and vendor SoC telemetry 408. Telemetry generator nodes 402 generate telemetry which is transmitted to a telemetry collector 412 at the edge 410. Telemetry Collector 412 is depicted forwarding telemetry data to a software service 420 which forwards at least some of the data to telemetry encode 440 to produce compressed telemetry 442 which may be stored in edge database 450 where analytics 460 may be performed. FIG. 4 further depicts within edge platform 410, a telemetry decoder 453 coupled to database 450 and analytics 460.

Transmission client 470 may transmit data to cloud domain 420. As depicted in FIG. 4, the cloud domain 420 includes its own database 482, and a backend analytics engine 424 both of which are depicted couple to a telemetry decoder 426 as disclosed herein.

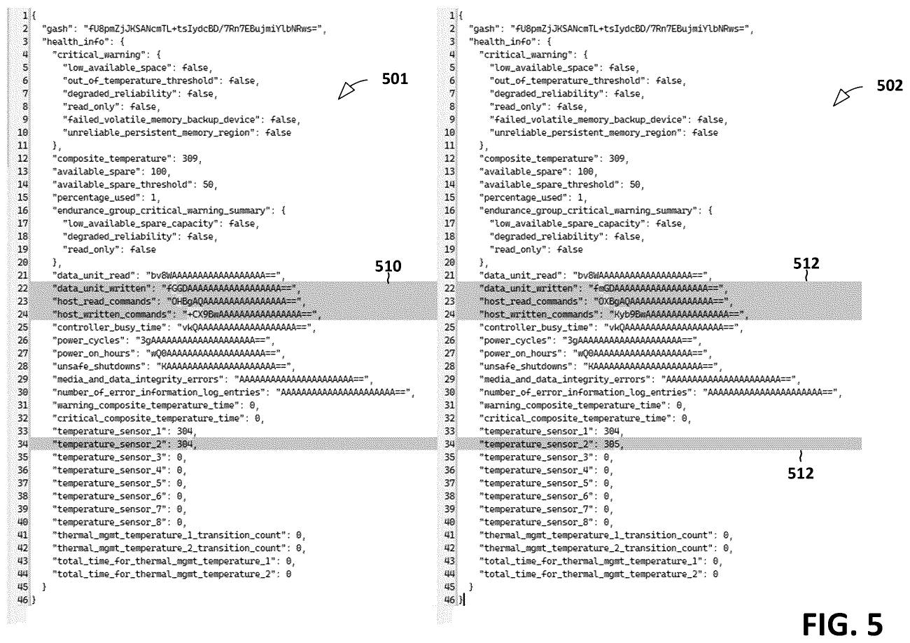

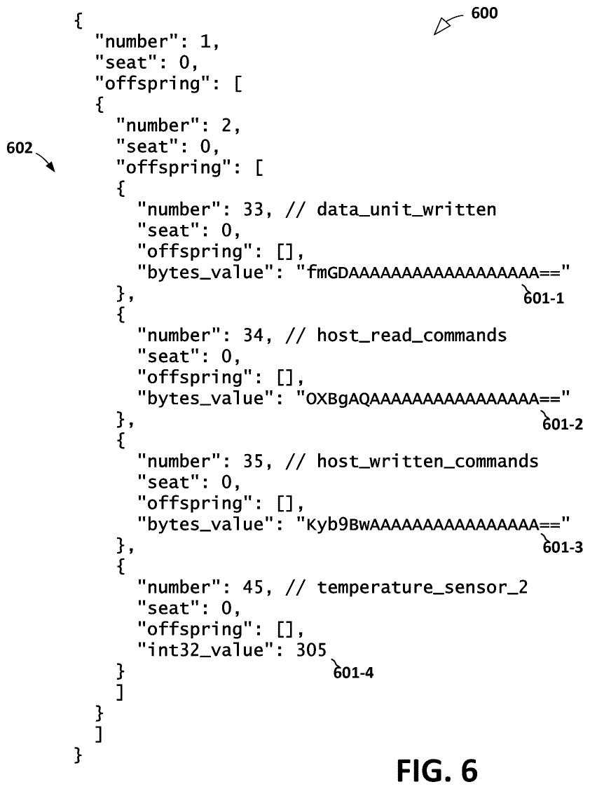

FIG. 5 and FIG. 6 illustrate an exemplary comparison operation performed between two telemetry samples 501 and 502, as depicted in FIG. 5. Comparison operations, comparing the two telemetry samples, are required to implement the disclosed features for lossless compression of telemetry data. As suggested by its name, the comparison operations identify differences in telemetry data values of two chronologically adjacent telemetry samples that share a common component identifier or (CID).

FIG. 5 includes highlighted telemetry data fields 510 in first telemetry sample 501 and highlighted data fields 512 in second telemetry sample 502. These highlighted data fields correspond to data fields with values that changed from the corresponding values in first telemetry sample 501.

The comparison operations identify all such data fields, as well as the changed value for each of these data fields, i.e., the data value in second telemetry sample 502, for inclusion in a patch for use in a different dependent record.

In at least one embodiment, the highlighted data fields are identified by creating an array to hold structured data, wherein each element of the array corresponds to an array index value (AIV) and includes a linked list of telemetry data fields corresponding to the AIV. For each value of the AIV from 1 to N, expand any links to identify all telemetry data endpoints for the telemetry data field corresponding to the AIV.

For telemetry data endpoints that differ between the subsequent sample and the preceding sample, save the value from the subsequent sample in a key value pair for inclusion in a patch and include structured data for navigating to the applicable telemetry data field.

Thus, in the example of FIG. 5, four telemetry data fields in second telemetry sample 502 have values that differ from the corresponding values in first telemetry sample 501. Specifically, the three telemetry data fields 512 and the telemetry data field 513.

FIG. 6 depicts an exemplary human readable representation of a patch 600 including the four changed values 601-1 through 601-4 and tree structure data 602 sufficient to navigate the structure of the telemetry sample to location the telemetry data field corresponding to capture the values in the four telemetry data fields of interest.

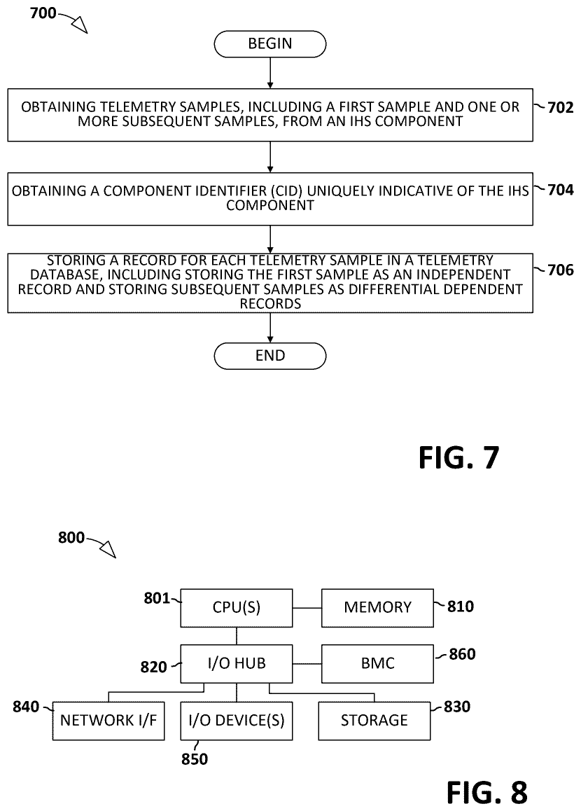

Referring now to FIG. 7, a flow diagram illustrates an exemplary telemetry management method 700. The method 700 depicted in FIG. 7 includes obtaining (step 702), from a component of an information handling system, telemetry samples including a first sample and one or more subsequent samples, The illustrated method further includes obtaining (step 704) a component identifier (CID) that is uniquely indicative of the component. Each telemetry sample may include a plurality of key value pairs and each telemetry sample from the same CID may share a common structure. Method 700 further includes storing (step 706) in a telemetry database, a record corresponding to each of the telemetry samples. The storing may further include storing the first sample as an independent record and storing subsequent samples as differential dependent records, in which the only telemetry data values are values that changed from a previous sample.

Disclosed features for managing telemetry data may be amendable to various specific use cases in which potentially critical telemetry data is being generated in contexts that are inherently resource constrained. As an example, an OEM may provision a platform with preboot telemetry functionality for usage and tracking analysis of critical features in the field. BIOS IQ from Dell Technologies is an example of this type of functionality. Preboot telemetry data can provide insight that could facilitate better user experience with right engineering methods. It could also influences business decisions like BIOS setup reduction. Disclosed features for lossless compression of telemetry data may be ideally suited for such use cases because preboot persistent storage is scare.

Another suitable use case for disclosed lossless compression techniques may be referred to as embedded controller (EC) out of band (OOB) telemetry. OOB telemetry collection requires a persistent space managed by the embedded controller (EC) within Non-Volatile Random Access Memory (NVRAM). The EC runtime data undergoes frequent changes, making it challenging to store data for an extended period due to limited space. Implementing disclosed lossless compression algorithm within the EC, specifically designed for storage optimization, could provide an ideal solution for managing telemetry footprint on bare-metal systems.

In another example, disclosed lossless compression features may adapt dynamically evolving data patterns, ensuring optimal compression ratios across diverse data sets with enhanced efficiency while maintaining data integrity and accessibility at the edge and cloud. Such a feature might be further extended by enabling a trigger condition for activating lossless compression features, such as when a storage space max out alert is issued, or free fall and shock event data is triggered for critical data sets related to security and service scenarios.

Referring now to FIG. 8, any one or more of the elements illustrated in FIG. 1 through FIG. 7 may be implemented as or within an information handling system exemplified by the information handling system 800 illustrated in FIG. 8. The illustrated information handling system includes one or more general purpose processors or central processing units (CPUs) 801 communicatively coupled to a memory resource 810 and to an input/output hub 820 to which various I/O resources and/or components are communicatively coupled. The I/O resources explicitly depicted in FIG. 8 include a network interface 840, commonly referred to as a NIC (network interface card), storage resources 830, and additional I/O devices, components, or resources 850 including as non-limiting examples, keyboards, mice, displays, printers, speakers, microphones, etc. The illustrated information handling system 800 includes a baseboard management controller (BMC) 860 providing, among other features and services, an out-of-band management resource which may be coupled to a management server (not depicted). In at least some embodiments, BMC 860 may manage information handling system 800 even when information handling system 800 is powered off or powered to a standby state. BMC 860 may include a processor, memory, an out-of-band network interface separate from and physically isolated from an in-band network interface of information handling system 800, and/or other embedded information handling resources. In certain embodiments, BMC 860 may include or may be an integral part of a remote access controller (e.g., a Dell Remote Access Controller or Integrated Dell Remote Access Controller) or a chassis management controller.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A method of managing telemetry data, comprising:
obtaining, from a component of an information handling system:
telemetry samples including a first sample and one or more subsequent samples; and
a component identifier (CID) wherein the CID is uniquely indicative of the component;
storing, in a telemetry database, a record corresponding to each of the telemetry samples, wherein said storing includes:
storing the first sample as an independent record; and
storing a subsequent sample as a differential dependent record indicative of one or more value differences, comprising differences between values in the subsequent sample and corresponding values in a preceding sample.

2. The method of claim 1, wherein:
each telemetry sample includes a structured plurality of key value pairs sharing a common structure; and
each record includes:
the CID;
a time stamp; and
a data values component (DVC) determined, at least in part, by the telemetry sample.

3. The method of claim 2, wherein the DVC for the independent record comprises an encoded telemetry sample encoded with a predetermined encoding scheme.

4. The method of claim 3, wherein the predetermined encoding scheme comprises a key-length-type-value (KLTV) encoding scheme comprising:
a key field comprising a number corresponding to a telemetry data field;
a value field comprising a value for the telemetry data field value;
a type field comprising a number indicative of a data type of the value field; and
a length field indicative of a length of the value field.

5. The method of claim 2, wherein the DVC for the dependent record comprises a patch, wherein the patch includes each of the value differences embedded within a tree structure indicative of a location of each of the value differences within the common structure of the telemetry samples.

6. The method of claim 2, wherein storing the subsequent sample as a differential dependent record includes performing structured comparison operations comprising:
creating an array to hold structured data indicative of the value differences, wherein each element of the array corresponds to an array index value (AIV) and includes a linked list of telemetry data fields corresponding to the AIV;
for each value of the AIV from 1 to N, expanding any links to identify all telemetry data endpoints for the telemetry data field corresponding to the AIV; and
for telemetry data endpoints that differ between the subsequent sample and the preceding sample, saving the value from the subsequent sample in a key value pair for inclusion in a patch and include structured data for navigating the telemetry structure.

7. The method of claim 1, further comprising performing decoding operations to recreate a telemetry data sample corresponding to a particular CID and timestamp from one or more records in the telemetry database sharing the CID, wherein the decoding operations include:
indexing the database with the CID and timestamp to identify a matching record;
responsive to determining the matching record is an independent record, extracting the sample from the matching record; and
responsive to determining the matching record is a dependent differential record:
indexing the database with the CID to identify:
a base record, comprising an independent record matching the CID; and
one or more intermediate records comprising one or more dependent differential records matching the CID and having an earlier timestamp than the particular timestamp;
merging the one or more tree structures of the one or more intermediate records to form a patch;
patching the base record to obtain an independent record matching the CID and timestamp; and
extracting the same from the matching record.

8. The method of claim 1, wherein the CID is determined based on a concatenation of values for two more identifying parameters and wherein the two or more identifying parameters include at least one of: an electronic piece part identifier (ePPID), a service tag, a serial number, a model name; and wherein the CID comprises a hash value generating by hashing the concatenation in accordance with a hashing algorithm.

9. The method of claim 1, further comprising: invoking the method for use in conjunction with preboot telemetry features for optimizing scarce persistent storage in a preboot environment.

10. The method of claim 1, further comprising: invoking the method for use in conjunction with embedded controller (EC) out of band, runtime telemetry for optimizing scarce EC storage.

11. An information handling system, comprising:
a central processing unit (CPU); and
a memory including processor-executable instructions that, when executed by the CPU, cause the system to perform telemetry data management operations including:
obtaining, from a component of an information handling system:
telemetry samples including a first sample and one or more subsequent samples; and
a component identifier (CID) wherein the CID is uniquely indicative of the component; and
storing, in a telemetry database, a record corresponding to each of the telemetry samples, wherein said storing includes:
storing the first sample as an independent record; and
storing a subsequent sample as a differential dependent record indicative of one or more value differences, comprising differences between values in the subsequent sample and corresponding values in a preceding sample.

12. The information handling system of claim 11, wherein:
each telemetry sample includes a structured plurality of key value pairs sharing a common structure; and
each record includes:
the CID;
a time stamp; and
a data values component (DVC) determined, at least in part, by the telemetry sample.

13. The information handling system of claim 12, wherein the DVC for the independent record comprises an encoded telemetry sample encoded with a predetermined encoding scheme.

14. The information handling system of claim 13, wherein the predetermined encoding scheme comprises a key-length-type-value (KLTV) encoding scheme comprising:
a key field comprising a number corresponding to a telemetry data field;
a value field comprising a value for the telemetry data field value;
a type field comprising a number indicative of a data type of the value field; and
a length field indicative of a length of the value field.

15. The information handling system of claim 12, wherein the DVC for the dependent record comprises a patch, wherein the patch includes each of the value differences embedded within a tree structure indicative of a location of each of the value differences within the common structure of the telemetry samples.

16. The information handling system of claim 12, wherein storing the subsequent sample as a differential dependent record includes performing structured comparison operations comprising:
creating an array to hold structured data indicative of the value differences, wherein each element of the array corresponds to an array index value (AIV) and includes a linked list of telemetry data fields corresponding to the AIV;
for each value of the AIV from 1 to N, expanding any links to identify all telemetry data endpoints for the telemetry data field corresponding to the AIV; and
for telemetry data endpoints that differ between the subsequent sample and the preceding sample, saving the value from the subsequent sample in a key value pair for inclusion in a patch and include structured data for navigating the telemetry structure.

17. The information handling system of claim 11, further comprising performing decoding operations to recreate a telemetry data sample corresponding to a particular CID and timestamp from one or more records in the telemetry database sharing the CID, wherein the decoding operations include:
indexing the database with the CID and timestamp to identify a matching record;
responsive to determining the matching record is an independent record, extracting the sample from the matching record; and
responsive to determining the matching record is a dependent differential record:
indexing the database with the CID to identify:
a base record, comprising an independent record matching the CID; and
one or more intermediate records comprising one or more dependent differential records matching the CID and having an earlier timestamp than the particular timestamp;
merging the one or more tree structures of the one or more intermediate records to form a patch;
patching the base record to obtain an independent record matching the CID and timestamp; and
extracting the same from the matching record.

18. The information handling system of claim 11, wherein the CID is determined based on a concatenation of values for two or more identifying parameters.

19. The information handling system of claim 11, further comprising: invoking the method for use in conjunction with preboot telemetry features for optimizing scarce persistent storage in a preboot environment.

20. The information handling system of claim 11, further comprising: invoking the method for use in conjunction with embedded controller (EC) out of band, runtime telemetry for optimizing scarce EC storage.
